(19) United States
(12) Patent Application Publication
(10) Pub. No.: US 2009/0238372 A1
(43) Pub. Date: Sep. 24, 2009

(54) VERTICALLY OR HORIZONTALLY PLACEABLE COMBINATIVE ARRAY SPEAKER

(76) Inventor: Wei HSU, Chung Ho City (TW)

Correspondence Address: Muncy, Geissler, Olds & Lowe, PLLC, P.O. BOX 1364, FAIRFAX, VA, 22038-1364, US

(21) Appl. No.: 12/246,131

(22) Filed: Oct. 6, 2008

(30) Foreign Application Priority Data
Mar. 20, 2008 (TW) 097109914

(51) Int. Cl. H04R 3/12; H03F 99/00

(52) U.S. Cl. 381/61; 381/120; 381/182

(57) ABSTRACT

The present invention provides a vertically or horizontally placeable combinative array speaker. The vertically or horizontally placeable combinative array speaker includes a microprocessor, an orientation sensor coupled to the microprocessor to sense condition changes of the combinative array speaker, a sound field reconstructing unit formed within or outside of the combinative array speaker, wherein the sound field reconstructing unit is coupled to the microprocessor to simulate surround sounds, and array speakers coupled to the sound field reconstructing unit through an amplifier.

### FIELD OF THE INVENTION

The present invention relates to an array speaker, and more particularly to a vertically or horizontally placeable combinative array speaker which can achieve surround sound effects.

### BACKGROUND OF THE INVENTION

The current trend in sound reproduction is to use an arrangement of typically four to five loudspeakers. For example, a conventional speaker system includes a front speaker located in proximity to the video image for providing acoustic output based upon a summation signal of the component left and right (L+R) channels of the audio signal. A rear speaker located to the rear of the viewing area provides acoustic output based upon a difference signal, (L−R) or (R−L), between the left and right channels. Left and right speakers located to the respective left and right sides of the viewing area. The left and right channels speakers reproduce a difference signal, (L−˜R) or (R−˜L), where ˜ is a gain which may vary or may be a value fixed between zero and unity. Output to the left and right speakers is band limited to substantially filter out frequency components below a predetermined threshold. A bass speaker may also be provided to output the low frequency components of a (L+R) summation signal. The (L+R) summation signal input to the front speaker assists in localizing dialog to the video image. The (L−˜R) or (R−˜L) difference signal substantially removes dialog sound so that the side and rear speaker output primarily comprises sonic ambience and surround sound effects. Band limiting the left and right speakers further assists in localizing dialog to the video image.

The conventional surround-sound speaker systems as mentioned above usually need four to five speakers located in different positions to reproduce surround sound effects and the positions of these speakers are substantially unchangeable. Therefore, the user needs to arrange space for different speakers in different directions in a room. It is inconvenient and space-wasting for the user. Thus, there is still a demand for providing a space-saving and position changeable surround-sound speaker.

### SUMMARY OF THE INVENTION

The present invention provides a vertically or horizontally placeable combinative array speaker. In one aspect of the present invention, the vertically or horizontally placeable combinative array speaker includes a microprocessor; an orientation sensor coupled to the microprocessor to sense condition changes of the combinative array speaker; a sound field reconstructing unit formed within or outside of the combinative array speaker, wherein the sound field reconstructing unit is coupled to the microprocessor to simulate surround sounds; and array speakers coupled to the sound field reconstructing unit through an amplifier. The array speakers include at least a bass speaker, at least two alt speakers, and at least two passive plates. The sound field reconstructing unit includes a digital signal processor and a digital delay circuit.

One advantage of the present invention is that the vertically or horizontally placeable combinative array speaker can singly achieve surround sound effects.

Another advantage of the present invention is that the vertically or horizontally placeable combinative array speaker can be combined vertically or horizontally to provide a customized surround sound speaker.

Still another advantage of the present invention is that the vertically or horizontally placeable combinative array speaker can be combined vertically or horizontally to provide a speaker with power and speaker sizes which the user desires.

Yet another advantage of the present invention is that the vertically or horizontally placeable combinative array speaker can be placed anywhere in a room with the surround sound effects remained at the same level.

Still another advantage of the present invention is that the vertically or horizontally placeable combinative array speaker is convenient to use and position changeable and space-saving for the user.

These and other advantages will become apparent from the following description of preferred embodiments taken together with the accompanying drawings and the appended claims.

### BRIEF DESCRIPTION OF THE DRAWINGS

The present invention may be understood by some preferred embodiments and detailed descriptions in the specification and the attached drawings below. The identical reference numbers in the drawings refer to the same components in the present invention. However, it should be appreciated that all the preferred embodiments of the invention are only for illustrating but not for limiting the scope of the Claims and wherein:

FIG. 1 and FIG. 2 are diagrams of an array speaker unit in accordance with one embodiment of the present invention;

FIG. 3 and FIG. 4 are diagrams of a combinative array speaker combined horizontally in accordance with one embodiment of the present invention;

FIG. 5 and FIG. 6 are diagrams of a combinative array speaker combined vertically in accordance with another embodiment of the present invention;

FIG. 7 is a diagram of a combinative array speaker in accordance with one embodiment of the present invention; and

FIG. 8 is a block diagram of a vertically or horizontally placeable combinative array speaker in accordance with one embodiment of the present invention.

### DETAILED DESCRIPTION OF THE PREFERRED EMBODIMENT

The invention will now be described with the preferred embodiments and aspects and these descriptions interpret structure and procedures of the invention only for illustrating but not for limiting the Claims of the invention. Therefore, except the preferred embodiments in the specification, the present invention may also be widely used in other embodiments.

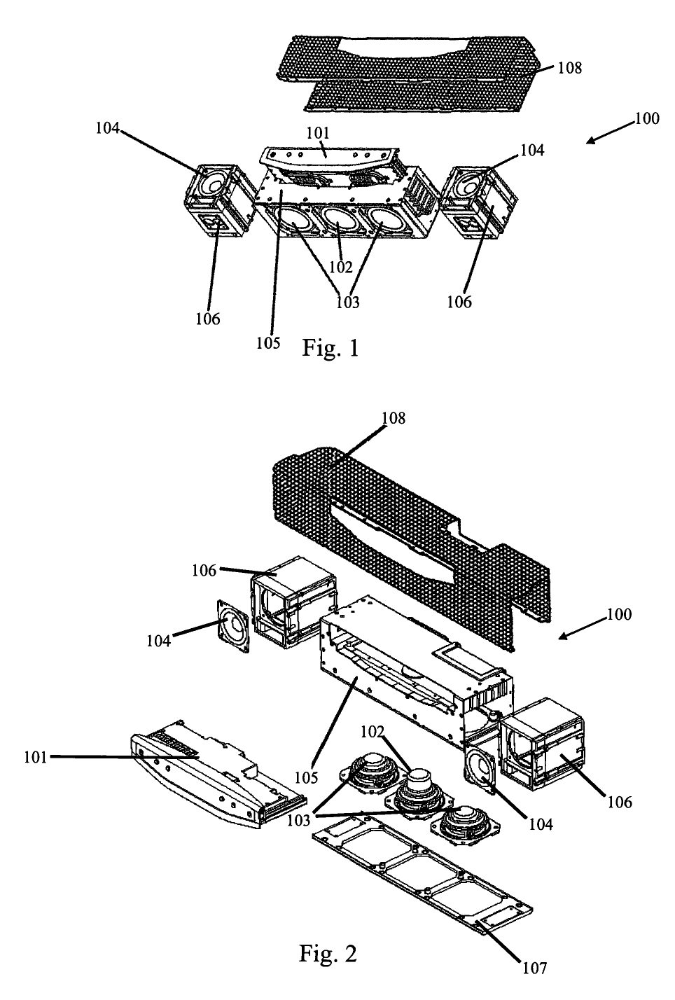

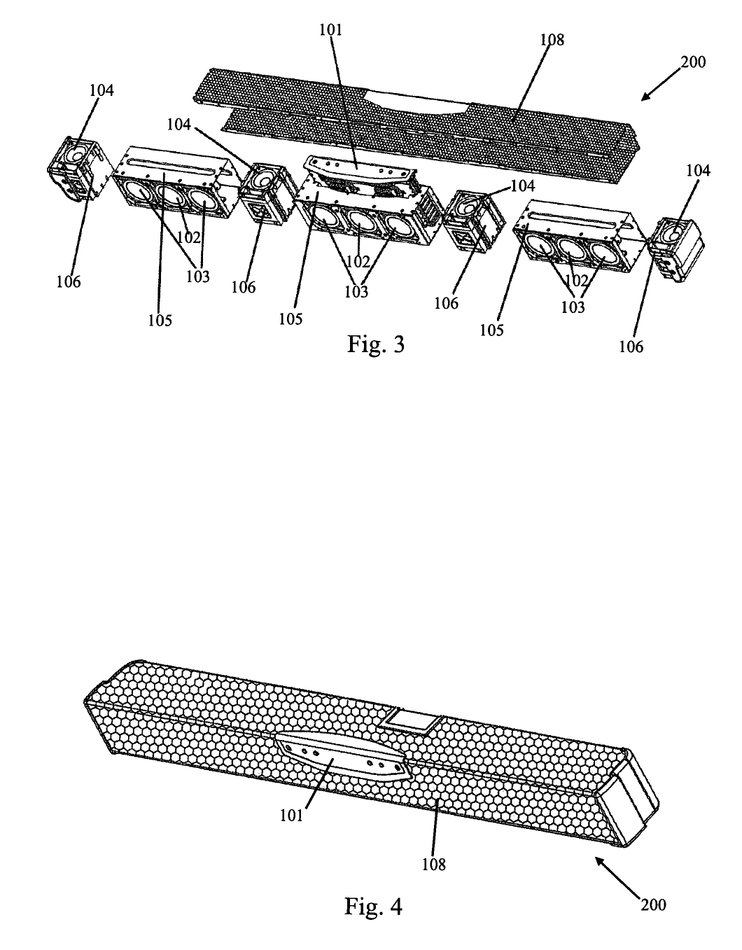

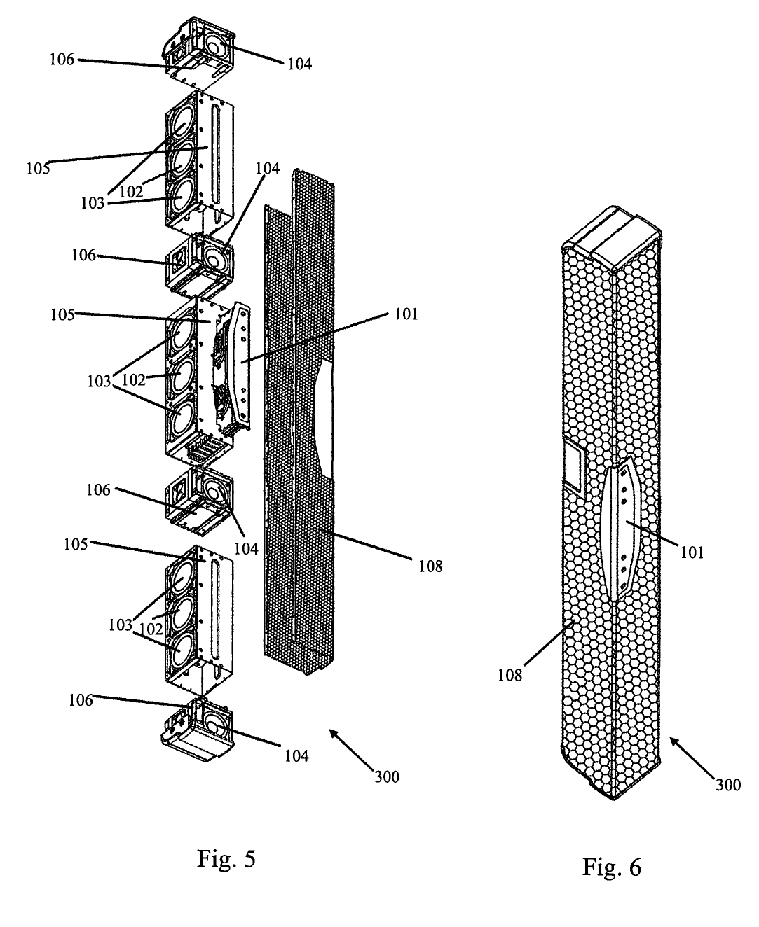

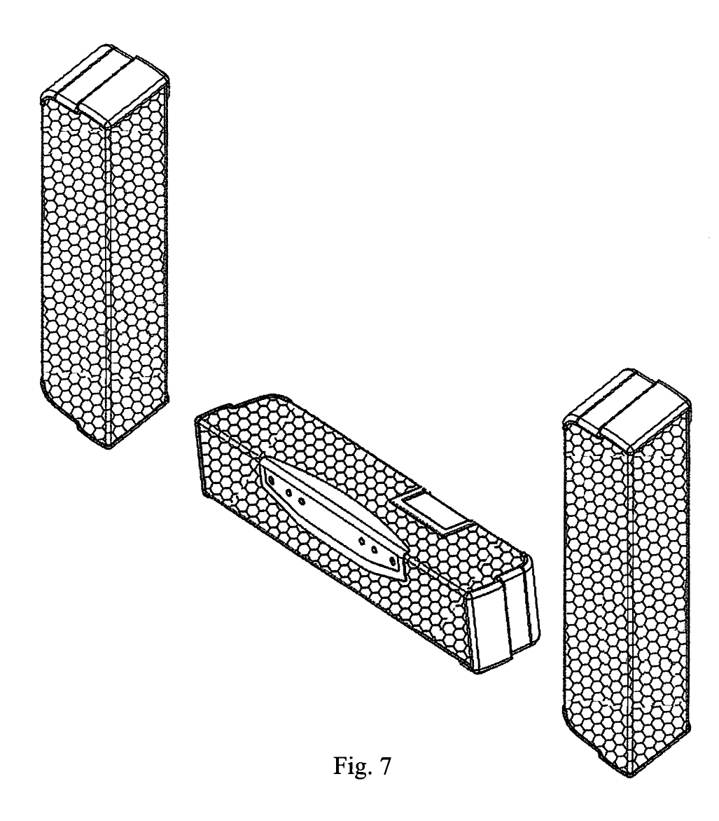

The present invention discloses a vertically or horizontally placeable combinative array speaker. In one embodiment of the present invention, the combinative array speaker may be a single array speaker unit as shown in FIG. 1, or a plurality of array speaker units combined vertically and linearly as shown in FIG. 3 and FIG. 4. Furthermore, in another embodiment of the present invention, the combinative array speaker may also be a plurality of array speaker units combined horizontally and linearly as shown in FIG. 5 and FIG. 6. In one embodiment of the present invention, the combinative array speaker may be placed vertically or horizontally at the user's pleasure. Moreover, the combinative array speaker may be three or more single array speaker units separately placed in three or more positions as shown in FIG. 7. The vertically or horizontally placeable combinative array speaker of the present invention achieves surround sound effects under a linear combination or a user-desired combination and under a vertical or horizontal placement by the combination of the array speaker units and by an orientation sensor and a 3D sound field reconstruction technique which will be described hereafter. Because each speaker in the array speaker unit plays different roles under the horizontal placement and the vertical placement, there are different play modes in the combinative array speaker for the horizontal placement and the vertical placement. The vertically or horizontally placeable combinative array speaker of the present invention utilizes the orientation sensor to sense condition changes of the combinative array speaker between the vertical placement and the horizontal placement to change the play mode. The orientation sensor may be a mercury sensor or a gravity sensor.

Referring to FIG. 1 and FIG. 2, in one embodiment of the present invention, the array speaker unit 100 includes a control circuit 101, a bass speaker 102, passive plates 103, alt speakers 104, a housing 105, housings 106, a bottom plate 107, and a speaker mesh 108. The control circuit 101 is disposed in the front of the housing 105 and above the bass speaker 102 and the passive plates 103, and is coupled to the bass speaker 102, the passive plates 103 and the alt speakers 104 to control the operation of each speaker driver and provide audio input/output interfaces. The bass speaker 102 and the passive plates 103 are disposed in the openings in the lower surface of the housing 105, and the bass speaker 102 is disposed between two passive plates 103 to produce resonance with the passive plates 103 to increase bass. The alt speakers 104 are disposed in the front of the housings 106 and on two sides of the housing 105 separately to produce alt sound forwards. The bass speaker 102, the passive plates 103 and the alt speakers 104 are coupled with each other parallelly or serially. The housing 105 and the housings 106 may be coupled with each other by grooves or any other structures. The bottom plate 107 is disposed on the bottom side of both the bass speaker 102 and the passive plates 103 to fix the bass speaker 102 and the passive plates 103 onto the housing 105. The speaker mesh 108 is disposed on the housing 105 and the housings 106 to cover them.

Referring to FIG. 3 and FIG. 4, in one embodiment of the present invention, each speaker driver in the array speaker unit 100 may be combined horizontally in the form of the array speaker unit 100 and be covered with the speaker mesh 108 to form a horizontally combined combinative array speaker 200. Referring to FIG. 5 and FIG. 6, in another embodiment of the present invention, each speaker driver in the array speaker unit 100 may be combined vertically in the form of the array speaker unit 100 and be covered with the speaker mesh 108 to form a vertically combined combinative array speaker 300. Furthermore, the combinative array speaker may include one horizontally placed array speaker and two vertically placed array speakers as shown in FIG. 7. It should be noted that the number of the combinations of the array speaker unit 100 is not limited by the aforementioned embodiments, such that the array speaker unit 100 may be vertically or horizontally combined in any numbers to form a combinative array speaker which provides power and speaker sizes that the user desires, so as to be placed in accordance with furniture and decoration in the user's house.

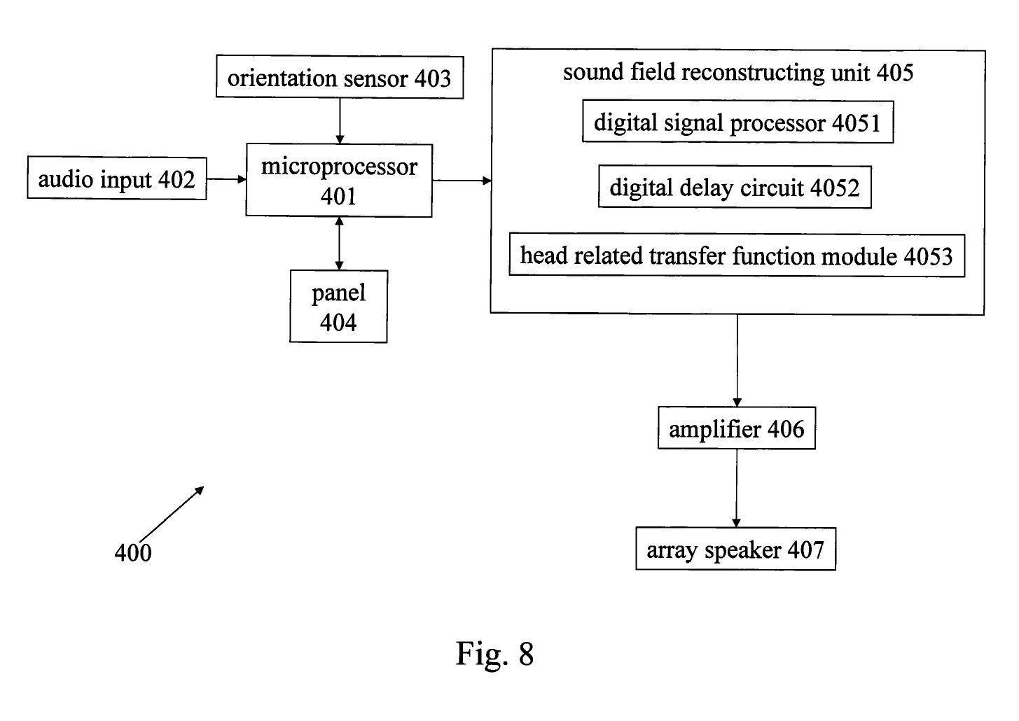

Referring to FIG. 8, in one embodiment of the present invention, the vertically or horizontally placeable combinative array speaker 400 includes a microprocessor 401, an audio input 402, an orientation sensor 403, a panel 404, a sound field reconstructing unit 405, an amplifier 406, and an array speaker 407. As shown in FIG. 8, the array speaker 407 is coupled to the sound field reconstructing unit 405 through the amplifier 406 to receive sound signals treated by the sound field reconstructing unit 405 and the amplifier 406. The vertically or horizontally placeable combinative array speaker 400 can achieve surround sound effects under a linear combination or a user-desired combination and under a vertical or horizontal placement by the combination of the array speaker units and by the orientation sensor 403 and the sound field reconstructing unit 405. The sound field reconstructing unit 405 and the orientation sensor 403 are formed in the control circuit 401 and coupled to the microprocessor 401. In order to attain the purpose of the present invention, the sound field reconstructing unit 405 is required, wherein the sound field reconstructing unit 405 mainly includes a Digital Signal Processor (DSP) 4051, a digital delay circuit 4052, and a HRTF (Head Related Transfer Function) module 4053 to clearly reproduce localized sound image utilizing the 3D sound field reconstruction technique by real-time digital filtering, by dynamic compression algorithm, and by rebuilding approximate time delay for different sounds. It should be noted that the sound field reconstructing unit 405 may be provided outside the vertically or horizontally placeable combinative array speaker 400 or embedded therein. The 3D sound field reconstruction technique also includes rich HRTF (Head Related Transfer Function) database, latest sound field simulation technology, such as BIEM (Boundary Integral Equation Method) and FEM (Finite Element Method), virtual sound source technology, subjective measurement technology, and sound stage conversion technology which allows the vertically or horizontally placeable combinative array speaker 400 to reproduce a clear sound imaging with minimum sound quality change such as the reflection and reverberation element etc. The high quality reproduction digital filters are realized by the Digital Signal Processor (DSP) 4051 and implemented by HRTF module 4053 with measurement database as well as full theoretical model. The 3D sound field reconstruction technique creates an extremely wide sound stage without introducing any noticeable coloration of the original signal and generates the illusion of five virtual loudspeakers from the aforementioned combinations of the array speaker units by filtering to achieve surround sound.

In order to simulate real sound source, which locates at an arbitrary point in 3D space, the 3D sound field reconstruction technique introduces HRTF (Head Related Transfer Function) database, which was defined as a set of transfer function between sound source to two ears of a human head. The HRTF depends on the coordinate and frequency of a point of sound source, and also has individual dependency of the listeners. HRTF can be realized as an impulse response of the time domain representation of HRTF referred as HRIR (Head Related Impulse Response). This HRTF or HRIR consists of a complete mathematical model based on acoustic wave theory and actual measurements that have been carried out for huge samples using dummy head microphones and human heads. The theoretical HRTF has several advantages such as suitable characteristics for music reproduction due to its natural and simple frequency response and less computational tasks.

Therefore, the vertically or horizontally placeable combinative array speaker 400 of the present invention utilizes the sound field reconstructing unit 405 to simulate real surround sound and produce treated sound signals from audio input 402 for the array speaker 407 under different combinations to output toward different directions, so as to achieve surround sound effects under a linear combination or a user-desired combination. Because each speaker in the array speaker unit plays different roles under the horizontal placement and the vertical placement, there are different play modes in the combinative array speaker for the horizontal placement and the vertical placement. Therefore, the vertically or horizontally placeable combinative array speaker 400 of the present invention utilizes the orientation sensor 403 to sense condition changes of the combinative array speaker between the vertical placement and the horizontal placement and then output the sensed condition to the control circuit 101 to switch the play mode, so as to achieve surround sound effects no matter under the vertical or horizontal placement. The orientation sensor 403 can sense changes of gravity in the combinative array speaker and send signals to the microprocessor 401 when the vector of the gravity changes to switch related circuits. Furthermore, the vertically or horizontally placeable combinative array speaker of the present invention can be placed anywhere in a room with the surround sound effects remained at the same level. Accordingly, the vertically or horizontally placeable combinative array speaker of the present invention can be convenient to use and position changeable and space-saving for the user, and can be combined vertically or horizontally to provide a customized surround sound speaker.

The foregoing description is a preferred embodiment of the present invention. It should be appreciated that this embodiment is described for purposes of illustration only, not for limiting, and that numerous alterations and modifications may be practiced by those skilled in the art without departing from the spirit and scope of the invention. It is intended that all such modifications and alterations are included insofar as they come within the scope of the invention as claimed or the equivalents thereof.

What is claimed is:

1. A structure of a vertically or horizontally placeable combinative array speaker, comprising:
a microprocessor;
an orientation sensor coupled to said microprocessor to sense condition changes of said combinative array speaker;
a sound field reconstructing unit formed within or outside of said combinative array speaker, wherein said sound field reconstructing unit is coupled to said microprocessor to simulate surround sounds; and
array speakers coupled to said sound field reconstructing unit through an amplifier.

2. The structure of claim 1, wherein said array speakers comprise at least a bass speaker, at least two alt speakers, and at least two passive plates.

3. The structure of claim 2, wherein said bass speaker, said alt speakers, and said passive plates are coupled with each other parallelly or serially.

4. The structure of claim 2, wherein said bass speaker, said alt speakers, and said passive plates are disposed vertically and linearly.

5. The structure of claim 2, wherein said bass speaker, said alt speakers, and said passive plates are disposed horizontally and linearly.

6. The structure of claim 1, wherein said combinative array speaker comprises a horizontally placed array speaker and at least a vertically placed array speaker.

7. The structure of claim 1, wherein said sound field reconstructing unit comprises a digital signal processor.

8. The structure of claim 1, wherein said sound field reconstructing unit further comprises a digital delay circuit.

9. The structure of claim 1, wherein said orientation sensor comprises a mercury sensor.

10. The structure of claim 1, wherein said orientation sensor comprises a gravity sensor.
